(19) United States
(12) Patent Application Publication
(10) Pub. No.: US 2016/0019971 A1
(43) Pub. Date: Jan. 21, 2016

(54) NONVOLATILE SEMICONDUCTOR MEMORY DEVICE AND METHOD OF CONTROLLING THE SAME

(71) Applicant: KABUSHIKI KAISHA TOSHIBA, Minato-ku (JP)

(72) Inventor: Hideto HORII, Yokkaichi-shi (JP)

(73) Assignee: KABUSHIKI KAISHA TOSHIBA, Minato-ku (JP)

(21) Appl. No.: 14/640,563

(22) Filed: Mar. 6, 2015

Related U.S. Application Data
(60) Provisional application No. 62/025,770, filed on Jul. 17, 2014.

(51) Int. Cl. G11C 16/26; G11C 16/04

(52) U.S. Cl. CPC G11C 16/26; G11C 16/0483

(57) ABSTRACT

According to an embodiment, a non-volatile semiconductor memory device comprises a NAND cell unit, a bit-line, a source-line, word-lines and a control circuit. The NAND cell unit comprises memory cells connected in series. The bit-line is connected to an end of the NAND cell unit. The source-line is connected to the other end of the NAND cell unit. The word-lines are connected to respective control gates of the memory cells. The control circuit applies, to a non-selected word-line on the bit-line side of a predetermined boundary in the NAND cell unit, a first read-pass voltage turning on the memory cell regardless of the cell data. The control circuit applies, to a non-selected word-line on the source-line side of the predetermined boundary, a second read-pass voltage less than the first read-pass voltage. The control circuit provides a read bit-line voltage between the bit-line and the source-line.

### CROSS-REFERENCE TO RELATED APPLICATIONS

This application is based upon and claims the benefit of U.S. Provisional Patent Application No. 62/025,770, filed on Jul. 17, 2014, the entire contents of which are incorporated herein by reference.

### FIELD

Embodiments described herein relate to a non-volatile semiconductor memory device and a method of controlling the same.

### BACKGROUND

### Description of the Related Art

A memory cell configuring a nonvolatile semiconductor memory device such as a NAND type flash memory includes a semiconductor layer, a control gate, and a floating gate. The memory cell changes its threshold voltage according to a charge accumulated in a charge accumulation film to store a magnitude of this threshold voltage as data. In recent years, enlargement of capacity and raising of integration level has been proceeding in such a nonvolatile semiconductor memory device.

### BRIEF DESCRIPTION OF THE DRAWINGS

FIG. 1 is a block diagram of a non-volatile semiconductor memory device according to a first embodiment.

FIG. 2 is a circuit diagram showing the configuration of a memory cell array of the non-volatile semiconductor memory device.

FIG. 3 is a schematic cross-sectional view of memory cells and select gate transistors.

FIG. 4 is a histogram showing a threshold distribution of a memory cell MC according to a comparative example.

FIG. 5 is a schematic cross-sectional view of the memory cells and the select gate transistors for illustrating a reading method according to the comparative example.

FIG. 6 is a timing diagram for illustrating the reading method according to the comparative example.

FIG. 7 is a diagram schematically showing the voltage relationship between a semiconductor layer, a charge accumulation layer, and a control gate in the reading method according to the comparative example.

FIG. 8 is a diagram schematically showing the voltage relationship between the semiconductor layer, the charge accumulation layer, and the control gate in the reading method according to the comparative example.

FIG. 9 is a schematic cross-sectional view of a memory cell and a select gate transistor for illustrating a reading method according to the first embodiment.

FIG. 10 is a timing diagram for illustrating the reading method.

FIG. 11 is a diagram schematically showing the voltage relationship between a semiconductor layer, a charge accumulation layer, and a control gate in the reading method.

FIG. 12 is a diagram schematically showing the voltage relationship between the semiconductor layer, the charge accumulation layer, and the control gate in the reading method.

FIG. 13 is a graph showing a result of a simulation for illustrating how much read disturb is reduced by the reading method.

FIG. 14 is a schematic cross-sectional view of a memory cell and a select gate transistor for illustrating a reading method according to a second embodiment.

FIG. 15 is a timing diagram for illustrating the reading method.

FIG. 16 is a diagram schematically showing the voltage relationship between a semiconductor layer, a charge accumulation layer, and a control gate in the reading method according to the second embodiment.

FIG. 17 is a schematic cross-sectional view of a memory cell and a select gate transistor for illustrating a reading method according to a third embodiment.

FIG. 18 is a timing diagram for illustrating the reading method.

FIG. 19 is a diagram schematically showing the voltage relationship between a semiconductor layer, a charge accumulation layer, and a control gate in the reading method.

FIG. 20 is a diagram schematically showing the voltage relationship between a semiconductor layer, a charge accumulation layer, and a control gate in the reading method.

FIG. 21 is a schematic cross-sectional view of a memory cell and a select gate transistor for illustrating a reading method according to a fourth embodiment.

FIG. 22 is a schematic cross-sectional view of the memory cell and the select gate transistor for illustrating the reading method.

FIG. 23 is a timing diagram for illustrating the reading method.

FIG. 24 is a diagram schematically showing the voltage relationship between a semiconductor layer, a charge accumulation layer, and a control gate in the reading method.

FIG. 25 is a schematic perspective view of the configuration of a memory cell array according to a fifth embodiment.

FIG. 26 is an enlarged cross-sectional view showing the configuration of a portion of the memory cell array shown in FIG. 25.

### DETAILED DESCRIPTION

A non-volatile semiconductor memory device according to the embodiments described below comprises a NAND cell unit, a bit-line, a source-line, a plurality of word-lines and a control circuit. The NAND cell unit comprises a plurality of memory cells connected in series and storing the same bit number of data. The bit-line is connected to an end of the NAND cell unit. The source-line is connected to the other end of the NAND cell unit. The plurality of word-lines is connected to respective control gates of the memory cells. The control circuit controls voltage of the bit-line, the source-line and the plurality of the word-lines. The control circuit applies a read voltage to a selected word-line connected to a selected memory cell. The read voltage turns on or turns off the selected memory cell according to a cell data stored to the selected memory cell. In addition, the control circuit applies to a non-selected word-line connected to a non-selected memory cell positioned on the bit-line side of a predetermined boundary in the NAND cell unit and positioned farther from the selected memory cell than a predetermined value, a first read-pass voltage turning on the memory cell regardless of the cell data. An amount of the first read-pass voltage is regardless of a position of the selected memory cell. In addition, the control circuit provides to a non-selected word-line connected to a non-selected memory cell positioned on the source-line side of the predetermined boundary and positioned farther from the selected memory cell than a predetermined value, a second read-pass voltage less than the first read-pass voltage. An amount of the second read-pass voltage is regardless of the position of the selected memory cell.

A method of controlling a non-volatile semiconductor memory device according to the embodiments described below is a method of controlling a non-volatile semiconductor memory device comprising the above-mentioned memory cell array and control circuit. The control method applies a read voltage to a selected word-line connected to the selected memory cell. The read voltage turns on or turns off the selected memory cell according to a cell data stored to the selected memory cell. In addition, the control method applies, to a non-selected word-line connected to a non-selected memory cell positioned on the bit-line side of a predetermined boundary in the NAND cell unit and positioned farther from the selected memory cell than a predetermined value, a first read-pass voltage turning on the memory cell regardless of the cell data. An amount of the first read-pass voltage is regardless of a position of the selected memory cell. In addition, the reading method applies, to a non-selected word-line connected to a non-selected memory cell positioned on the source-line side of a predetermined boundary and positioned farther from the selected memory cell than a predetermined value, a second read-pass voltage less than the first read-pass voltage. An amount of the second read-pass voltage is regardless of the position of the selected memory cell.

Referring now to the drawings, embodiments of the non-volatile semiconductor memory device and the method of controlling the same will be described. Note that values such as a voltage value shown in the specification are for illustration purpose only, and they may be changed as appropriate.

### First Embodiment

### Entire Configuration

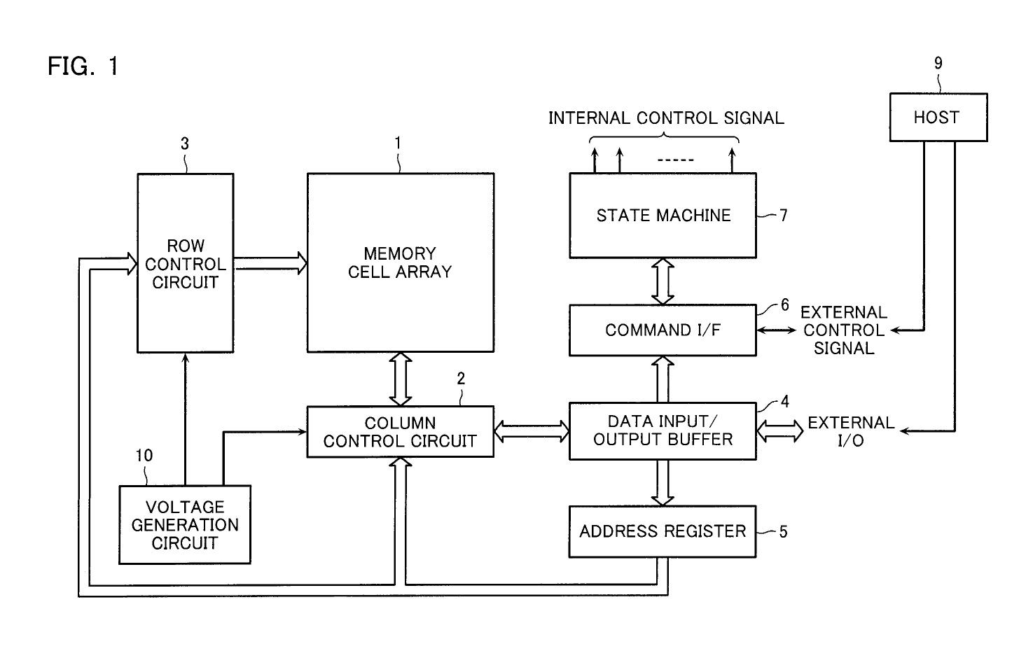

FIG. 1 is a block diagram of a non-volatile semiconductor memory device according to a first embodiment. This nonvolatile semiconductor memory device includes a memory cell array 1 having a plurality of memory cells MC disposed substantially in a matrix therein, and comprising a bit line BL and a word line WL disposed orthogonally to each other and connected to these memory cells MC. Provided in a periphery of this memory cell array 1 are a column control circuit 2 and a row control circuit 3. The column control circuit 2 controls the bit line BL and performs data erase of the memory cell, data write to the memory cell, and data read from the memory cell. The row control circuit 3 selects the word line WL and applies a voltage for data erase of the memory cell, data write to the memory cell, and data read from the memory cell.

A data input/output buffer 4 is connected to an external host 9, via an I/O line, and receives write data, receives an erase command, outputs read data, and receives address data or command data. The data input/output buffer 4 sends received write data to the column control circuit 2, and receives data read from the column control circuit 2 to be outputted to external. An address supplied to the data input/output buffer 4 from external is sent to the column control circuit 2 and the row control circuit 3 via an address register 5.

Moreover, a command supplied to the data input/output buffer 4 from the host 9 is sent to a command interface 6. The command interface 6 receives an external control signal from the host 9, determines whether data inputted to the data input/output buffer 4 is write data or a command or an address, and, if a command, receives the data and transfers the data to a state machine 7 as a command signal.

The state machine 7 performs management of this nonvolatile semiconductor memory device overall, receives a command from the host 9, via the command interface 6, and performs management of read, write, erase, input/output of data, and so on.

In addition, it is also possible for the external host 9 to receive status information managed by the state machine 7 and judge an operation result. Moreover, this status information is utilized also in control of write and erase.

Furthermore, the state machine 7 controls a voltage generating circuit 10. This control enables the voltage generating circuit 10 to output a pulse of any voltage and any timing.

Now, the pulse formed by the voltage generating circuit 10 can be transferred to any line selected by the column control circuit 2 and the row control circuit 3. These column control circuit 2, row control circuit 3, state machine 7, voltage generating circuit 10, and so on, configure a control circuit in the present embodiment.

[Memory Cell Array]

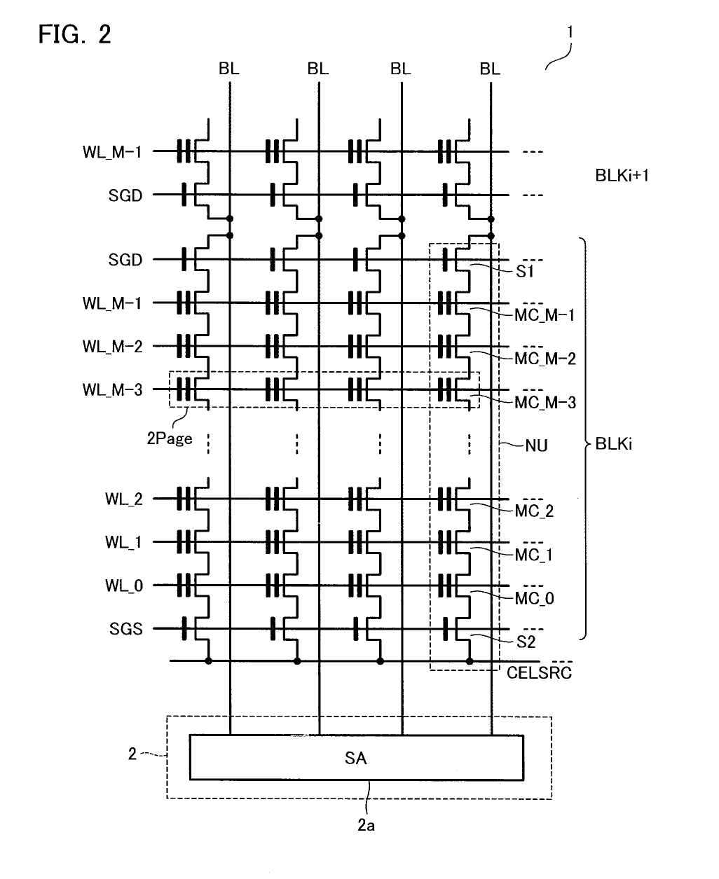

FIG. 2 is a circuit diagram showing a configuration of the memory cell array 1. As shown in FIG. 2, the memory cell array 1 is configured having NAND cell units NU arranged therein, each of the NAND cell units NU being configured having a NAND string and select gate transistors S1 and S2 respectively connected to both ends of the NAND string, the NAND string having M electrically rewritable nonvolatile memory cells MC_0 to MC_M−1 connected in series therein, sharing a source and a drain.

The NAND cell unit NU has one end (a select gate transistor S1 side) connected to the bit line BL and the other end (a select gate transistor S2 side) connected to a common source line CELSRC. Gate electrodes of the select gate transistors S1 and S2 are connected to select gate lines SGD and SGS. In addition, control gate electrodes of the memory cells MC_0 to MC_M−1 are respectively connected to word lines WL_0 to WL_M−1. The bit line BL is connected to a sense amplifier 2a of the column control circuit 2, and the word lines WL_0 to WL_M−1 and select gate lines SGD and SGS are connected to the row control circuit 3.

In the case of 2 bits/cell where 2 bits of data are stored in one memory cell MC, data stored in the plurality of memory cells MC connected to one word line WL configures 2 pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 1 is M, and, in the case of 2 bits/cell, the number of pages in one block is M×2 pages.

Note that although not shown in FIG. 2, the memory cell array 1 may comprise a dummy cell between the select gate transistors S1/S2 and the memory cells MC_0/MC_M−1 positioned in the end portions of the NAND cell unit NU. Additionally, in the case that 2 bits or 4 bits of data is stored to one memory cell MC, between memory cells storing the same bit number of data MC_0, MC_M−1 and the select gate transistors S1, S2, other memory cells storing 1 bit or 2 bits of data may be applied.

[Configurations of Memory Cell MC and Select Gate Transistors S1 and S2]

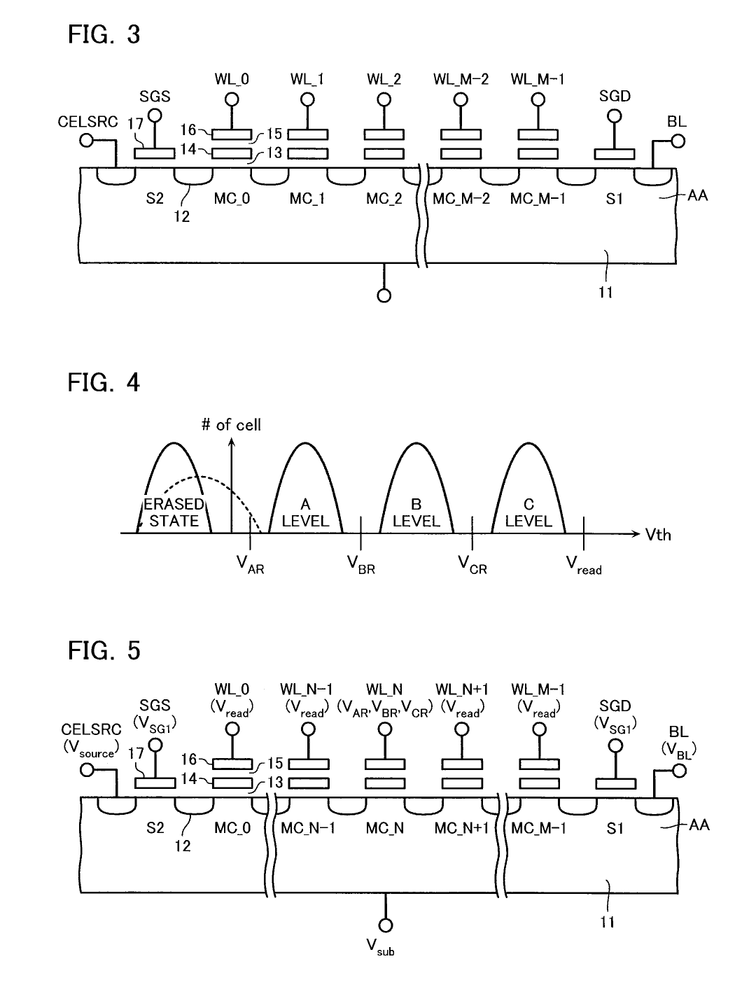

FIG. 3 is a schematic cross-sectional view of the memory cells MC_0 to MC_M−1 and the select gate transistors S1 and S2. As shown in FIG. 3, in a semiconductor layer AA in a surface of a p-type well 11 formed in a substrate, an n-type diffusion layer 12 is formed. The n-type diffusion layer 12 functions as a source and a drain of a MOSFET composing the memory cell MC. In addition, above the semiconductor layer AA, via a tunnel insulating film 13, a charge accumulation layer 14 (CA) functioning as a charge accumulation layer is formed, and above the charge accumulation layer 14, via an inter-gate dielectric film 15, a control gate 16 is formed. The control gate 16 forms a part of the word-line WL. In addition, the select gate transistors S1 and S2 comprises selection gates 17 above the well 11 via the gate-insulating film 13. The selection gates 17 form a part of the select gate lines SGS and SGD. The memory cells MC and the select gate transistors S1 and S2 are NAND connected such that the adjacent ones share a drain and a source.

[Data Storage State of Memory Cell MC According to Comparative Example]

Next, with reference to FIG. 4, a threshold voltage distribution which is the data storage state of memory cells MC according to a comparative example is described. FIG. 4 is a histogram showing threshold voltage distributions in case of 2-bit/cell. The x-axis schematically shows the amount of threshold voltage of the memory cells MC and the y-axis schematically shows the number of memory cells MC. Note that the threshold voltage here is a word-line voltage necessary for switching a memory cell MC to the ON state. In addition, although 2-bit/cell is given as an example here, the embodiments described below are not limited thereto.

In the threshold voltage distribution of data, from the lower side of the threshold voltage, four types of threshold voltage distributions (an erased state, an A level, a B level, and a C level) are provided. These threshold voltage distributions are allocated with, for example, four types of data “11”, “01”, “00”, and “10”. Note that the distribution shown by the dotted line in FIG. 4 will be described below.

A read voltage V_{AR} applied between the semiconductor layer AA and the word-line WL switches the memory cells MC in the erased state to the ON state and switches the memory cells MC in the A level, B level, and C level to the OFF state. A read voltage V_{BR} applied between the semiconductor layer AA and the word-line WL switches the memory cells MC in the erased state and the A level to the ON state and switches the memory cells MC in the B level and the C level to the OFF state. A read voltage V_{CR} applied between the semiconductor layer AA and the word-line WL switches the memory cells MC in the erased state, the A level, and the B level to the ON state and switches the memory cells MC in the C level to the OFF state. A read-pass voltage V_{read} applied between the semiconductor layer AA and the word-line WL switches all memory cells MC to the ON state.

[Read Operation According to Comparative Example]

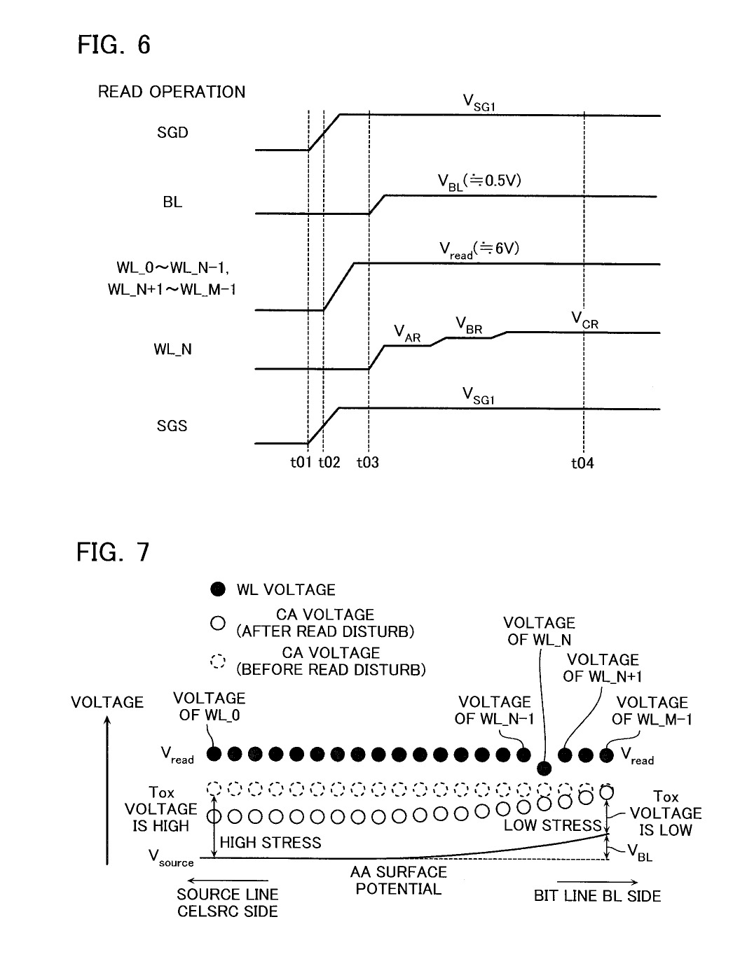

Next, with reference to FIG. 5 and FIG. 6, a read operation according to the comparative example will be described. FIG. 5 is a schematic cross-sectional view of the memory cells MC_0 to MC_M−1 and the select gate transistors S1 and S2 for illustrating the read operation according to the comparative example. Note that in the following discussion, the memory cell MC subjected to the read operation is referred to as a selected memory cell MC_N (0≦N≦M−1). In addition, the word-line WL_N connected to the selected memory cell MC_N is referred to as a selected word-line WL_N. In addition, other memory cell MC than the selected memory cell MC_N is referred to as a non-selected memory cell MC. In addition, the word-line WL connected to the non-selected memory cell MC is referred to as a non-selected word-line WL.

As shown in FIG. 5, in the read operation according to the comparative example, the voltages of the select gate lines SGD and SGS are raised to a gate voltage V_{SG1} to switch the select gate transistors S1 and S2 to the ON state. In addition, the voltages of the non-selected word-lines WL_0 to WL_N−1 and the non-selected word-lines WL_N+1 to WL_M−1 are raised to the read-pass voltage V_{read} to switch the non-selected memory cells MC_0 to MC_N−1 and the MC_N+1 to MC_M−1 to the ON state. In addition, the voltage of the source-line CELSRC is set to a source voltage V_{source} and the voltage of the bit-line BL is raised to a read bit-line voltage V_{BL}. Thus, a bias voltage is applied between the source and drain of the selected memory cell MC_N. Then, the voltage of the selected word-line WL_N is set to the read voltages V_{AR}, V_{BR}, and V_{CR}. Note that the well 11 is applied with a voltage V_{SUB} of about the ground voltage.

FIG. 6 is a timing diagram for illustrating the read operation according to the comparative example. As shown in FIG. 6, at a timing when the read operation according to the comparative example is started, all voltages of the select gate lines SGD and SGS, the bit-line BL, and the word-lines WL are set to about 0 V (ground voltage).

As shown in FIG. 6, at a timing t01, the voltage of the select gate lines SGD and SGS are raised to the gate voltage V_{SG1} to switch the select gate transistors S1 and S2 to the ON state.

As shown in FIG. 6, at a timing t02, the voltages of the non-selected word-lines WL_0 to WL_N−1 and the non-selected word-lines WL_N+1 to WL_M−1 are raised to the read-pass voltage V_{read} (for example, about 6V). This switches the non-selected memory cells MC_{—}0 to MC_N−1 and MC_N+1 to MC_M−1 to the ON state, thereby changing the voltage of the semiconductor layer AA of them to the source voltage V_{source}. Note that the source voltage V_{source} is set to the ground voltage.

As shown in FIG. 6, at a timing t03, the voltage of the bit-line BL is raised to the read bit-line voltage V_{BL} (for example, about 0.5 V). Thus, a bias voltage is applied between the source and drain of the selected memory cell MC_N.

In addition, as shown in FIG. 6, from the timing t03, the voltage of the selected word-line WL_N is sequentially increased to the read voltage of V_{AR} to V_{CR} corresponding to the respective reading levels. By this, the selected memory cell MC_N is switched to the ON state at a timing corresponding to the threshold voltage, and current starts to flow through the bit-line BL.

Therefore, timing t04 at which the bit-line BL starts to conduct current may be sensed by the sense amplifier 2a to determine data held in the selected memory cell MC_N.

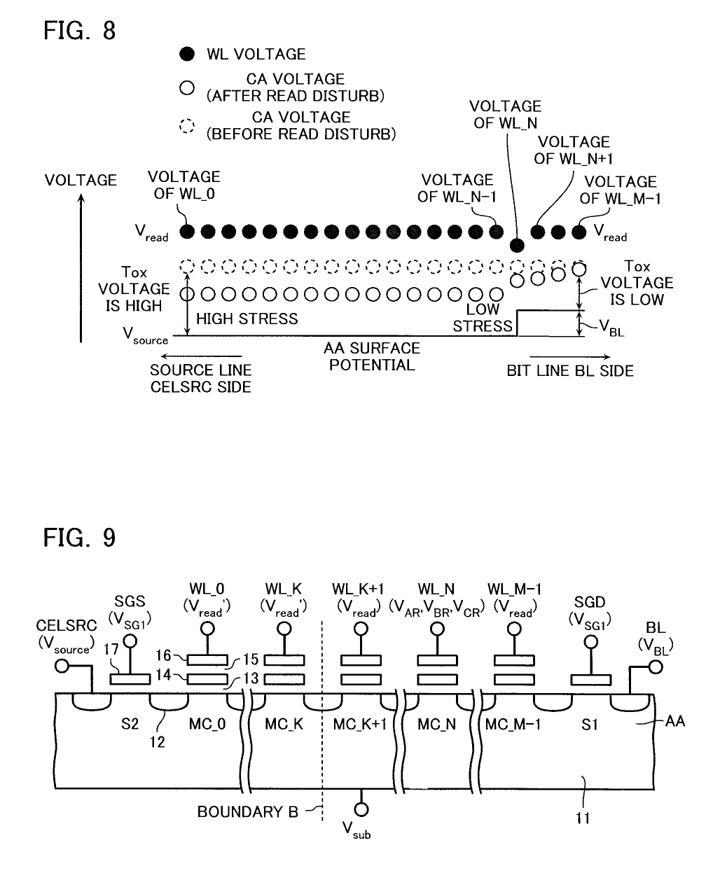

Next, with reference to FIG. 7 and FIG. 8, problems in the read operation according to the comparative example will be described. FIG. 7 and FIG. 8 are diagrams schematically showing the voltage relationship between the semiconductor layer AA, the charge accumulation layer CA, and the word-lines WL for the selected memory cell MC_N being in the ON and OFF states, respectively, in the read operation according to the comparative example. In addition, in FIG. 7 and FIG. 8, the open circles with dotted lines represent the voltage of the charge accumulation layer CA and the closed circles represent the voltage of the word-lines WL. In addition, the open circles with solid lines represent an example of the voltage of the charge accumulation layer CA after the so-called read disturb occurs, as described below.

As shown by the solid line in FIG. 7, if the selected memory cell MC_N is in the ON state, the potential of the semiconductor layer AA surface in a NAND cell unit is distributed to gradually decrease from the bit-line BL side to the source-line CELSRC side. And, the potential gradient of the semiconductor layer AA in the NAND cell unit is larger with being closer to the bit-line BL and smaller with being closer to the source-line CELSRC. This is because the potential of the semiconductor layer AA surface is higher with being closer to a bit-line BL and, as the over drive voltage is low, the resistivity of the semiconductor layer AA is higher with being closer to the bit-line BL.

In addition, as shown by the closed circles in FIG. 7, all non-selected word-lines WL_0 to WL_N−1 and WL_N+1 to WL_M−1 are applied with the same read-pass voltage V_{read}. In FIG. 7, as it is assumed for purposes of illustration that all cells have the same data, by the read-pass voltage V_{read} being applied to all non-selected word-lines WL_0 to WL_N−1 and WL_N+1 to WL_M−1, the voltages of the charge accumulation layers CA are raised to almost uniform voltage.

As described above, the potential of the semiconductor layer AA surface is distributed to gradually decrease from the bit-line BL side to the source-line CELSRC side, and all non-selected word-lines WL_0 to WL_N−1 and WL_N+1 to WL_M−1 have a constant voltage. Thus, the potential difference (hereinafter referred to as a “Tox voltage”) between the semiconductor layer AA and the charge accumulation layer CA gradually increases from the bit-line BL side to the source-line CELSRC side.

Here, the Tox voltage in the read operation is sufficiently lower than the Tox voltage in the write operation. However, the read operation is performed more frequently than the write operation. Thus, a relatively high Tox voltage is applied for a long time, which may cause a phenomenon (Read Disturb) that injects charges into the charge accumulation layers CA, thus changing the threshold voltages of the memory cells MC. Note that as shown by the dotted line in FIG. 4, the read disturb is most likely to occur in memory cells MC in the erased state.

In addition, the effect of the read disturb increases depending on the amount of Tox voltage. If, therefore, the read operation is repeated in the voltage state shown in FIG. 7 and each operation encounters the read disturb, the voltages of the charge accumulation layers CA gradually change toward the voltage of the semiconductor layer AA. That is, the effect of the read disturb is more likely to occur in a memory cell MC positioned near the source-line CELSRC. Note that the open circles with solid line in FIG. 7 represent example voltages of the charge accumulation layers CA during such a change process.

Meanwhile, as shown by the solid line in FIG. 8, if the selected memory cell MC_N is in the OFF state, the voltage of the semiconductor layer AA of the non-selected memory cells MC_N+1 to MC_M−1 positioned on the bit-line BL side of the selected memory cell MC_N is the read bit-line voltage V_{BL}. Meanwhile, the voltage of the semiconductor layer AA of the non-selected memory cells MC_0 to MC_N−1 positioned on the source-line CELSRC side of the selected memory cell MC_N is the source voltage V_{source}. That is, the potential of the semiconductor layer AA is changed in a stepped manner at the selected memory cell MC_N. Therefore, the Tox voltage is relatively low on the bit-line BL side of the selected memory cell MC_N and relatively high on the source-line CELSRC side of the selected memory cell MC_N.

As described above, the effect of the read disturb increases depending on the amount of the Tox voltage. If, therefore, the read operation is repeated in the voltage state shown in FIG. 8 and each operation encounters the read disturb, the voltages of the charge accumulation layers CA gradually change toward the voltage of the semiconductor layer AA. That is, the effect of the read disturb is likely to appear relatively small on the bit-line BL side of the selected memory cell MC_N and relatively large on the source-line CELSRC side. Here, a memory cell MC positioned near the source-line CELSRC is often positioned on the source-line CELSRC side of the selected memory cell MC_N. Therefore, even if the selected memory cell MC_N is in the OFF state, the effect of the read disturb is likely to appear relatively large. Note that the open circles with solid line in FIG. 8 represent example voltages of the charge accumulation layer CA during such a change process.

In addition, because the NAND cell unit is recently becoming finer and the material of the semiconductor layer AA is changing from single crystal silicon to polysilicon or the like, the semiconductor layer AA is becoming highly resistive. Therefore, in order for the semiconductor layer AA to conduct enough current to allow the sense amplifier 2a to distinguish the ON and OFF states, the read bit-line voltage V_{BL} is increasing. If the read bit-line voltage V_{BL} is increased, in the read operation, the voltage of the semiconductor layer AA of non-selected memory cells MC positioned near the bit-line BL is increased. Here, in the read operation, in order to also switch these non-selected memory cells MC positioned near the bit-line BL to the ON state, the read-pass voltage V_{read} also needs to be increased. Accordingly, the Tox voltage may further increase in the non-selected memory cells MC positioned near the source-line CELSRC, and thus the read disturb may be more likely to occur.

[Read Operation According to First Embodiment]

Next, with reference to FIG. 9 to FIG. 12, the read operation according to the first embodiment will be described. Note that in the following discussion, like elements as those in the above-described comparative example are designated with like reference symbols and their description is omitted here.

FIG. 9 is a schematic cross-sectional view of the memory cells MC_0 to MC_M−1 and the select gate transistors S1 and S2 for illustrating the read operation according to this embodiment. As shown in FIG. 9, in the read operation according to this embodiment, a predetermined boundary B is set in the NAND cell unit. Then, non-selected word-lines WL_K+1 to WL_M−1 connected to non-selected memory cells MC_K+1 to MC_M−1 positioned on the bit-line BL side of the predetermined boundary B are applied with the first read-pass voltage V_{read}. In addition, non-selected word-lines WL_0 to WL_K connected to non-selected memory cells MC_0 to MC_K positioned on the source-line CELSRC side of the predetermined boundary B are applied with a second read-pass voltage V_{read}′ less than the first read-pass voltage V_{read}. Note that although the boundary B is provided between the non-selected word-line WL_K and the non-selected word-line WL_K+1, this is merely an example.

Note that in the following discussion, the non-selected memory cells MC_K+1 to MC_M−1 positioned on the bit-line BL side of the predetermined boundary B are referred to as bit-line side non-selected memory cells MC_K+1 to MC_M−1. In addition, the non-selected memory cells MC_0 to MC_K positioned on the source-line CELSRC side of the predetermined boundary B are referred to as source-line side non-selected memory cells MC_0 to MC_K. In addition, the non-selected word-lines WL_K+1 to WL_M−1 connected to the bit-line side non-selected memory cells MC_K+1 to MC_M−1 are referred to as bit-line side non-selected word-lines WL_K+1 to WL_M−1. In addition, the non-selected word-lines WL_0 to WL_K connected to the source-line side non-selected memory cells MC_0 to MC_K are referred to as source-line side non-selected word-lines WL_0 to WL_K.

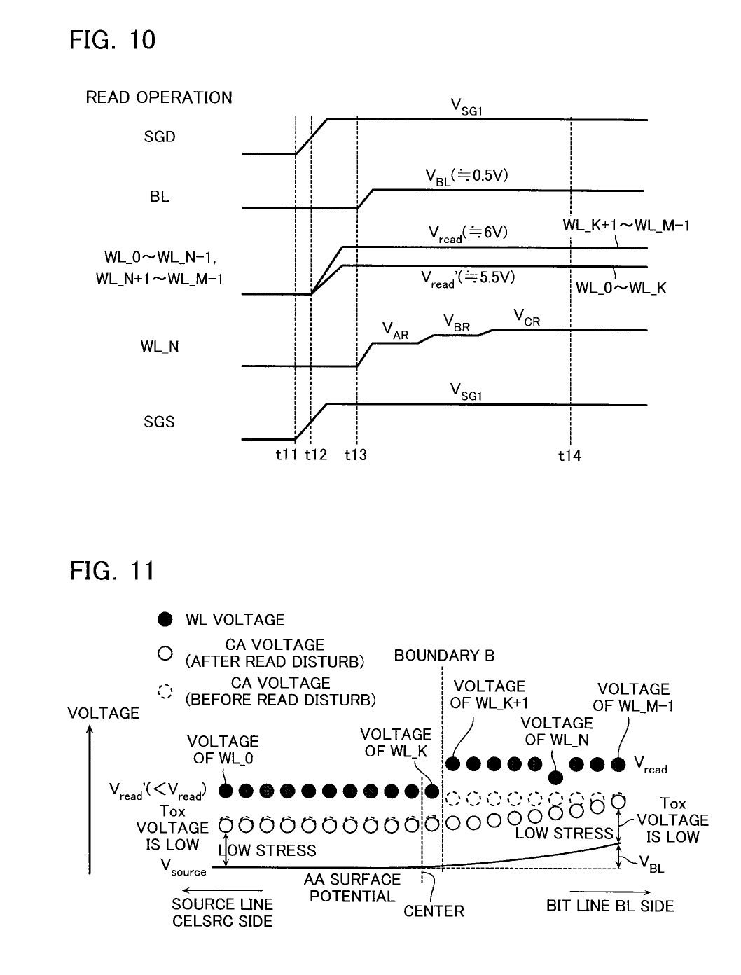

FIG. 10 is a timing diagram for illustrating the read operation according to this embodiment. As shown in FIG. 10, at a timing when the read operation according to this embodiment is started, all voltages of the select gate lines SGD and SGS, the bit-line BL, and the word-lines WL are set to about 0 V (ground voltage).

As shown in FIG. 10, at a timing t11, the voltage of the select gate lines SGD and SGS are raised to the gate voltage V_{SG1} to switch the select gate transistors S1 and S2 to the ON state.

As shown in FIG. 10, at a timing t12, the bit-line side non-selected word-lines WL_K+1 to WL_M−1 are applied with the first read-pass voltage V_{read} (for example, about 6 V). In addition, the source-line side non-selected word-lines WL_0 to WL_K are applied with the second read-pass voltage V_{read}′ (for example, about 5.5 V) less than the first read-pass voltage V_{read}. By this, the non-selected memory cells MC_0 to MC_N−1 and MC_N+1 to MC_M−1 are switched to the ON state, and the voltage of the semiconductor layer AA changes to the source voltage V_{source}. Note that the source voltage V_{source} is set to, by way of example, the ground voltage.

As shown in FIG. 10, at a timing t13, the voltage of the bit-line BL is raised to the read bit-line voltage V_{BL} (for example, about 0.5 V). Thus, a bias voltage is applied between the source and drain of the selected memory cell MC_N.

In addition, as shown in FIG. 10, from the timing t13, the voltage of the selected word-line WL_N is sequentially increased from the first read voltage of V_{AR} to V_{CR} corresponding to the respective reading levels. By this, the selected memory cell MC_N is switched to the ON state at a timing corresponding to the threshold voltage, and current starts to flow through the bit-line BL.

Therefore, timing t14 at which the bit-line BL starts to conduct current may be sensed by the sense amplifier 2a to determine data held in the selected memory cell MC_N.

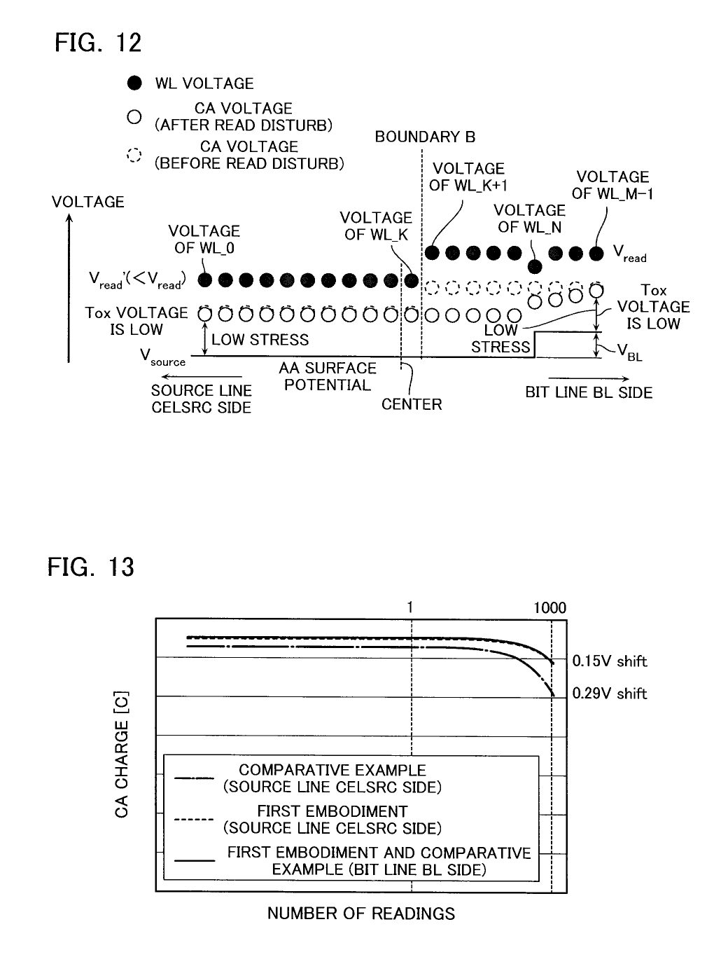

FIG. 11 and FIG. 12 are diagrams schematically showing the voltage relationship between the semiconductor layer AA, the charge accumulation layer CA, and the word-lines WL for the selected memory cell MC being in the ON and OFF states, respectively, in the read operation according to this embodiment. In addition, in FIG. 11 and FIG. 12, the open circles with dotted lines represent the voltage of the charge accumulation layer CA before the read disturb occurs, the open circles with solid lines represent the voltage of the charge accumulation layer CA after the read disturb occurs, and the closed circles represent the voltage of the word-lines WL.

As shown by the solid line in FIG. 11, if the selected memory cell MC_N is ON, the potential of the semiconductor layer AA in the NAND cell unit is distributed to gradually decrease from the bit-line BL side to the source-line CELSRC side. And, the potential gradient of the semiconductor layer AA in the NAND cell unit is larger with being closer to the bit-line BL and smaller with being closer to the source-line CELSRC.

In addition, as shown by the dotted line in FIG. 11, in the read operation according to this embodiment, the predetermined boundary B is set between the memory cell MC_K and the memory cell MC_K+1.

As shown by the closed circles in FIG. 11, the bit-line side non-selected word-lines WL_K+1 to WL_M−1 positioned on the bit-line BL side of the predetermined boundary B are applied with the first read-pass voltage V_{read}. By such a first read-pass voltage V_{read} being applied to the bit-line side non-selected word-lines WL_K+1 to WL_M−1, the voltage of the charge accumulation layer CA is raised to almost uniform voltage, thus the Tox voltage gradually increases from the bit-line BL side to the predetermined boundary B.

Meanwhile, as shown by the closed circles in FIG. 11, the source-line side non-selected word-lines WL_0 to WL_K positioned on the source-line CELSRC side of the predetermined boundary B are applied with the second read-pass voltage V_{read}′ less than the first read-pass voltage V_{read}. By such a second read-pass voltage V_{read}′ being applied to the source-line side non-selected word-lines WL_0 to WL_K, the voltage of the charge accumulation layer CA is raised to almost uniform voltage. Note, however, that the second read-pass voltage V_{read}′ applied to the source-line side non-selected word-lines WL_0 to WL_K is less than the first read-pass voltage V_{read}. Therefore, the voltage of the charge accumulation layer CA on the source-line CELSRC side of the predetermined boundary B is less than the voltage of the charge accumulation layer CA on the bit-line BL side. Therefore, the Tox voltage is also less than that according to the comparative example described with reference to FIG. 7, which may reduce the generation of the read disturb.

Meanwhile, as shown by the solid line in FIG. 12, if the selected memory cell MC_N is in the OFF state, the voltage of the semiconductor layer AA of the bit-line side non-selected memory cells MC_N+1 to MC_M−1 is the read bit-line voltage V_{BL}. Meanwhile, the voltage of the semiconductor layer AA of the source-line side non-selected memory cells MC_0 to MC_N−1 is the source voltage V_{source}. In other words, the voltage of the semiconductor layer AA is changed in a stepped manner at the selected memory cell MC_N.

In addition, as shown by the closed circles in FIG. 12, in the read operation according to this embodiment, the bit-line side non-selected word-lines WL_K+1 to WL_M−1 are applied with the first read-pass voltage V_{read}. By such a first read-pass voltage V_{read} being applied to the bit-line side non-selected word-lines WL_K+1 to WL_M−1, the voltage of the charge accumulation layer CA is raised to almost uniform voltage. Therefore, the Tox voltage is relatively low on the bit-line BL side of the selected memory cell MC_N, and relatively high on the predetermined boundary B side of the selected memory cell MC_N.

Meanwhile, the source-line side non-selected word-lines WL_{—} 0 to WL_K are applied with the second read-pass voltage V_{read}′ less than the first read-pass voltage V_{read}. It is considered that the application of the second read-pass voltage V_{read}′ to the source-line side non-selected word-lines WL_0 to WL_K raises the voltage of the charge accumulation layer CA to almost uniform voltage. Note, however, that the second read-pass voltage V_{read}′ applied to the source-line side non-selected word-lines WL_0 to WL_K is less than the first read-pass voltage V_{read}. Therefore, the potential of the charge accumulation layer CA on the source-line CELSRC side of the predetermined boundary B becomes is less than the voltage of the charge accumulation layer CA on the bit-line BL side. Therefore, the Tox voltage is also less than that according to the comparative example described with reference to FIG. 8, which may the reduce generation of the read disturb.

In other words, this embodiment decreases the non-selected word-line voltages of the source-line side non-selected word-lines WL_0 to WL_K positioned on the source-line CELSRC side of the predetermined boundary B. Thus, this embodiment may reduce the Tox voltages of the source-line side non-selected memory cells MC_0 to MC_N−1 and thus reduce the generation of the read disturb.

Note that this embodiment sets the above predetermined boundary B at a constant position regardless of the position of the selected memory cell MC_N. In addition, the bit-line side non-selected word-lines WL_K+1 to WL_M−1 are always applied with the first read-pass voltage V_{read}. Furthermore, the amounts of the first read-pass voltage V_{read} and the second read-pass voltage V_{read} are set at a constant value regardless of the position of the selected memory cell MC_N. Likewise, the source-line side non-selected word-lines WL_0 to WL_K are always applied with the second read-pass voltage V_{read}′. Therefore, predetermined voltages need only be transferred to predetermined word-lines WL, which can be achieved without employing a complicated configuration in the row control circuit 3 and the voltage generation circuit 10 or the like.

Note that as described above, if the selected memory cell MC_N is ON, the potential gradient of the semiconductor layer AA in the NAND cell unit is higher with being closer to the bit-line BL and lower with being closer to the source-line CELSRC. Therefore, in the memory cells MC disposed from near the source-line CELSRC to or beyond the center of the NAND cell unit, the voltage of the semiconductor layer AA may be roughly about the source voltage V_{source}. In view of the above, in this embodiment, the above predetermined boundary B is set at a position on the bit-line BL side of the NAND cell unit center.

In addition, the above second read-pass voltage V_{read}′ may be set less than the first read-pass voltage V_{read} by about the read bit-line voltage V_{BL}. It is considered, for example, that if the read bit-line voltage V_{BL} is about 0.5 V, the first read-pass voltage is set to about 6.0 V and the second read-pass voltage is set to about 5.5 V. Thus, the Tox voltages of the memory cells MC_0 to MC_K positioned on the source-line CELSRC side of the predetermined boundary B may be reduced to a value similar to the Tox voltage of the memory cell MC near the bit-line BL. In addition, it is considered that the difference between the second read-pass voltage V_{read}′ and the first read-pass voltage V_{read} is set to, for example, the read bit-line voltage V_{BL} or less.

Additionally, it is possible to apply a voltage different from the first read-pass voltage or the second read-pass voltage mentioned above to memory cells MC_N−1 and MC_N+1 adjacent to the selected memory cell MC_N, memory cells MC_N−2 and MC_N+2 further adjacent to these memory cells MC_N−1 or MC_N+1, or the like.

Next, with reference to FIG. 13, a description is given of how much the read disturb is reduced by the read operation according to this embodiment. The inventors performed a simulation to check how much the read disturb is reduced by the read operation according to this embodiment. In the simulation, the predetermined boundary is set for the NAND flash memory as described with reference to FIG. 3. In addition, the amount of charge (read disturb amount) is calculated. In the simulation, the charge accumulated in the charge accumulation layer 14 positioned on the bit-line BL side of the above predetermined boundary and the charge accumulation layer 14 positioned on the source-line CELSRC side of the above predetermined boundary is calculated. Moreover, in the simulation, the charge when the read operation according to the above comparative example is performed 1000 times and when the read operation according to this embodiment is performed 1000 times is calculated.

FIG. 13 is a graph showing the result of the simulation. The x-axis represents the number of readings and the y-axis represents the amount (read disturb amount) of charge accumulated in the charge accumulation layer 14 by the read disturb. In FIG. 13, the long and short dashed lines represents the amount (read disturb amount) of charge accumulated in the charge accumulation layer 14 positioned on the source-line CELSRC side of the above predetermined boundary after the read operation according to the comparative example is performed. In FIG. 13, the dotted line represents the amount of charge accumulated in the charge accumulation layer 14 positioned on the source-line CELSRC side of the above predetermined boundary after the read operation according to this embodiment is performed. In FIG. 13, the solid line represents the amount of charge accumulated in the charge accumulation layer 14 positioned on the bit-line BL side of the above predetermined boundary if the read operation according to this embodiment or the read operation according to the comparative example is performed. Note that in FIG. 13, for purposes of illustration, the dotted line and solid line are shifted in the vertical direction from the actual simulation results.

As shown by the solid line in FIG. 13, the simulation shows that the amount of charge accumulated in the charge accumulation layer 14 positioned on the bit-line BL side of a predetermined boundary increases at a similar pace for both of the reading method according to the comparative example and the reading method according to this embodiment.

Meanwhile, as shown by the dotted line and the long and short dashed lines in FIG. 13, the simulation shows that the amount of charge accumulated in the charge accumulation layer 14 positioned on the source-line CELSRC side of a predetermined boundary starts to increase when the number of readings exceeds a predetermined value for both of the read operation according to this embodiment and the read operation according to the comparative example. However, in the case that the read operation according to this embodiment is adopted, compared to the case that the read operation according to the comparative example is adopted, the speed at which the charge is accumulated in the charge accumulation layer 14 is reduced.

### Second Embodiment

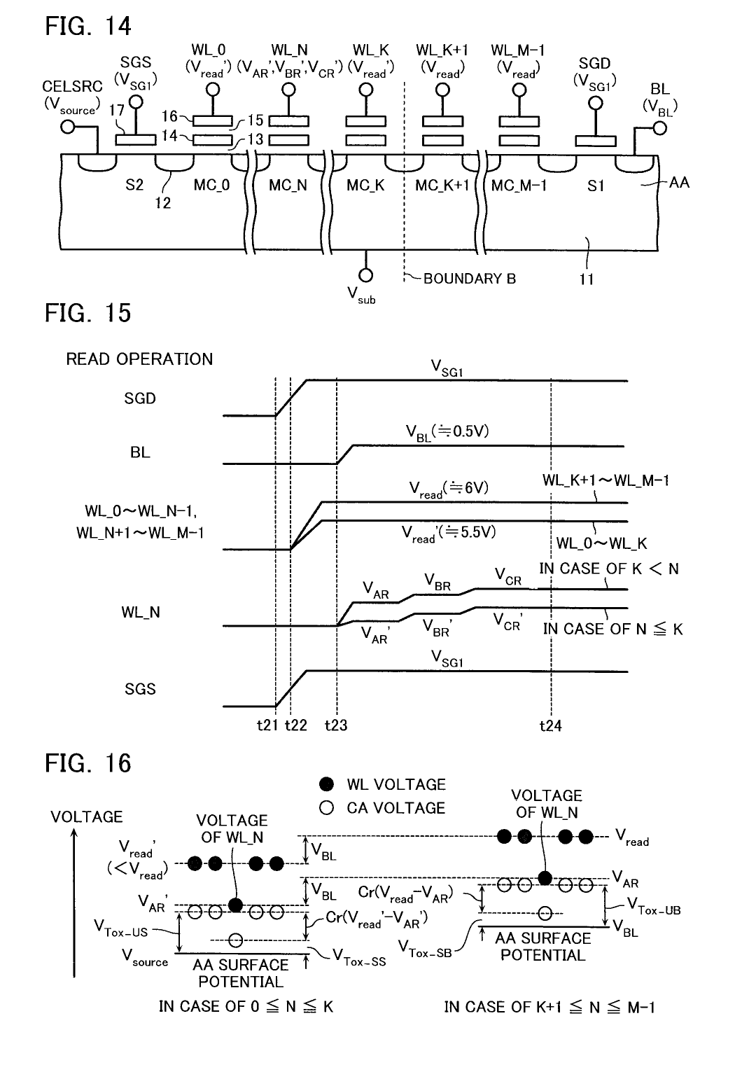

Next, with reference to FIG. 14 to FIG. 17, a read operation according to a second embodiment will be described. Note that in the following discussion, like elements as those in the first embodiment are designated with like reference symbols and their description is omitted here.

FIG. 14 is a schematic cross-sectional view of the memory cells MC_0 to MC_M−1 and the select gate transistors S1 and S2 for illustrating the read operation according to this embodiment. As described above, between memory cells MC positioned near the bit-line BL and memory cells MC positioned near the source-line CELSRC, the potential of the semiconductor layer AA is different. Therefore, if the same read voltage is used between when a memory cell MC positioned near the bit-line BL is selected and when a memory cell MC positioned near the source-line CELSRC is selected, the Tox voltages of the selected memory cells MC_N will be different. In this case, if a memory cell MC positioned near the source-line CELSRC is selected, the Tox voltage of the selected memory cell MC may become large, and a phenomenon in which a selected memory cell MC_N that is to be OFF is switched to the ON state (misreading) may be occur. Then, as shown in FIG. 14, in this embodiment, if the selected memory cell MC_N is positioned on the source-line CELSRC side of the predetermined boundary B (0≦N≦K), the selected word-line WL_N is applied with second read voltages V_{AR}′, V_{BR}′, and V_{CR}′ less than the first read voltages V_{AR}, V_{BR}, and V_{CR}. In addition, if the selected memory cell MC_N is positioned on the bit-line BL side of the predetermined boundary B (K+1≦N≦M−1), like the first embodiment, the selected word-line WL_N is applied with the first read voltages V_{AR}, V_{BR}, and V_{CR}. That is, in this embodiment, according to the potential of the semiconductor layer AA, not only the voltage of the non-selected word-lines WL, but also the voltage of the selected word-line WL_N is adjusted, thus the generation of the misreading is reduced.

FIG. 15 is a timing diagram for illustrating the read operation according to this embodiment. As shown in FIG. 15, in the read operation according to this embodiment, if the selected memory cell MC_N is set on the bit-line BL side of the predetermined boundary B (K<N), the read voltage applied to the selected memory cell MC_N is sequentially increased to V_{AR}, V_{BR}, and V_{CR} from timing t23. Meanwhile, if the selected memory cell MC_N is set on the source-line CELSRC side of the predetermined boundary B (N≦K), the read voltage applied to the selected memory cell MC_N is sequentially increased to V_{AR}′ less than V_{AR}, V_{BR}′ less than V_{BR}, and V_{CR}′ less than V_{CR} from timing t23. In addition, as shown in FIG. 15, the read operation according to this embodiment is similar in other respects to the read operation according to the first embodiment, and at timings t21 to t24, the operation at timings t11 to t14 described with reference to FIG. 10 is performed.

Next, with reference to FIG. 16, the Tox voltage of the selected memory cell MC_N in the read operation according to this embodiment will be described. FIG. 16 is a diagram schematically showing the voltage relationship between the semiconductor layer AA, the charge accumulation layer CA, and the word-lines WL in the read operation according to this embodiment. In addition, in FIG. 16, the open circles represent the voltage of the charge accumulation layer CA and the closed circles represent the voltage of the word-lines WL. Note that, in FIG. 16, an example where the selected memory cell MC_N is in the ON state is illustrated.

The right diagram in FIG. 16 shows the state if the selected memory cell MC_N is set on the bit-line BL side of the predetermined boundary B (K+1≦N≦M−1). As shown in the right diagram of FIG. 16, it is considered that if the selected memory cell MC_N is in the ON state, the potential of the semiconductor layer AA of the selected memory cell MC_N and the non-selected memory cells MC around it are almost similar. Therefore, the difference between the Tox voltage V_{Tox}_{_{—}}_{SB} of the selected memory cell MC_N and the Tox voltage V_{Tox}_{_{—}}_{UB} of the non-selected memory cells MC are represented by the voltage difference of the charge accumulation layers CA in these memory cells MC. Here, the voltage difference of the charge accumulation layers CA in the selected memory cell MC_N and the non-selected memory cells MC is about Cr (V_{read}−V_{AR}), where Cr is the coupling ratio.

The left diagram of FIG. 16 shows the state if the selected memory cell MC_N is set on the source-line CELSRC side of the predetermined boundary B (0≦N≦K). Again, the difference between the Tox voltage V_{Tox}_{_{—}}_{SS} of the selected memory cell MC_N and the Tox voltage V_{Tox}_{_{—}}_{US} of the non-selected memory cells MC is about the voltage difference Cr(V_{read}′−V_{AR}′) of the charge accumulation layers CA.

Here, as described above, in this embodiment, the Tox voltage V_{Tox}_{_{—}}_{US} of the non-selected memory cells MC near the source-line CELSRC is equal to the Tox voltage V_{Tox}_{_{—}}_{UB} of the non-selected memory cells MC near the bit-line BL. Therefore, in order to equally set the Tox voltages V_{Tox}_{_{—}}_{SB} and V_{Tox}_{_{—}}_{SS} of the selected memory cell MC_N, the Tox voltage differences Cr(V_{read}−V_{AR}) and Cr(V_{read}′−V_{AR}′) between the selected memory cell MC_N and the non-selected memory cells MC around it may be equalized. In this embodiment, by such a method, the Tox voltages of the selected memory cell MC_N may be adjusted to a similar value between when the selected memory cell MC_N is positioned on the bit-line BL side of the predetermined boundary B and when the selected memory cell MC_N is positioned on the source-line CELSRC side of the predetermined boundary B. This may suitably reduce the generation of the misreading.

In addition, the above predetermined boundary B is set to a constant position regardless of the position of the selected memory cell MC_N. In addition, if the selected memory cell MC_N is positioned on the bit-line BL side of the predetermined boundary B, the selected word-line WL_N is always applied with the first read voltages V_{AR}, V_{BR}, and V_{CR}. Likewise, if the selected memory cell MC_N is positioned on the source-line CELSRC side of the predetermined boundary B, the selected word-line WL_N is always applied with the second read voltages V_{AR}′, V_{BR}′, and V_{CR}′. Therefore, predetermined voltages need only be transferred to predetermined word-lines WL, which can be achieved without employing a complicated configuration in the row control circuit 3 and the voltage generation circuit 10 or the like.

Note that it is considered that the difference between the first read voltages (V_{AR}, V_{BR}, and V_{CR}) and the second read voltages (V_{AR}′, V_{BR}′, and V_{CR}′) is set similar to the difference between the first read-pass voltage V_{read} and the second read-pass voltage V_{read}′. Thus, between when the selected memory cell MC_N is positioned on the bit-line BL side of the predetermined boundary B and when the selected memory cell MC_N is positioned on the source-line CELSRC side of the predetermined boundary B, the Tox voltages of the selected memory cell MC_N may be made uniform, thus suitably reducing the generation of the misreading. As shown in FIG. 16, for example, it is considered that if the second read-pass voltage V_{read}′ is set to about the V_{read}−V_{BL}, the second read voltages V_{AR}′, V_{BR}′, and V_{CR}′ are set to about V_{AR}−V_{BL}, V_{BR}−V_{BL}, and V_{CR}−V_{BL}, respectively.

### Third Embodiment

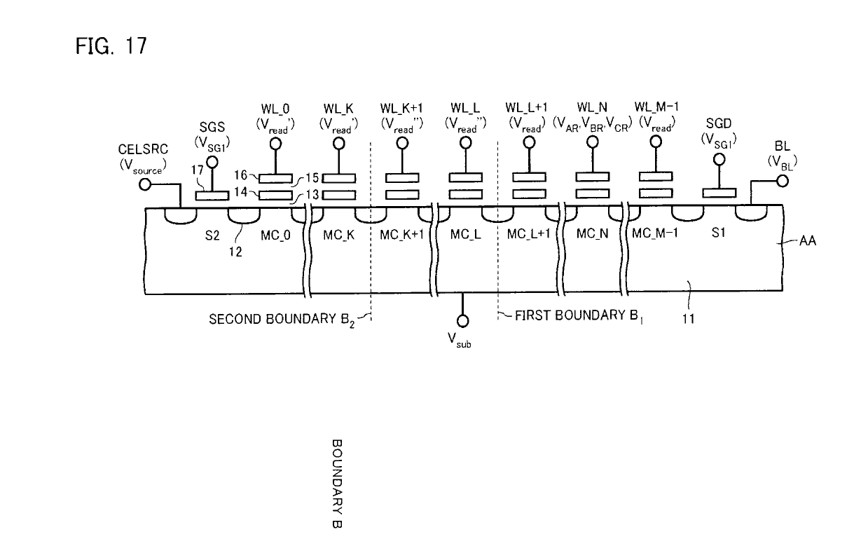

Next, with reference to FIG. 17 to FIG. 20, a non-volatile semiconductor memory device according to a third embodiment will be described. Note that in the following discussion, like elements as those in the read operation according to the second embodiment are designated with like reference symbols and their description is omitted here.

FIG. 17 is a schematic cross-sectional view of the memory cells MC_0 to MC_M−1 and the select gate transistors S1 and S2 for illustrating the read operation according to this embodiment. As described with reference to FIG. 9 and FIG. 14, in the read operations according to the first and second embodiments, one predetermined boundary B is set in the NAND cell unit and the voltages of non-selected word-lines WL and the selected word-line WL_N are differently adjusted utilizing the predetermined boundary B as a border. In contrast, as shown in FIG. 17, in the read operation according to this embodiment, two predetermined boundaries B₁ and B₂ are set in the NAND cell unit and the voltages of non-selected word-lines WL and the selected word-line WL_N are differently adjusted utilizing the predetermined boundaries B₁ and B₂ as borders. In other words, in this embodiment, according to the voltage of the semiconductor layer AA, the voltage of the word-lines WL is adjusted more flexibly, thus the generation of the read disturb and misreading are more suitably reduced.

Note that in the following discussion, a non-selected memory cell MC positioned on the bit-line BL side of the boundary B₁, which is the first boundary from the bit-line BL side, is referred to as a bit-line side non-selected memory cell MC. In addition, a non-selected memory cell MC positioned between the first boundary B₁ and the second boundary B₂ is referred to as a central region non-selected memory cell MC. In addition, a non-selected memory cell MC positioned on the source-line CELSRC side of the boundary B₂, which is the second boundary from the bit-line BL side, is referred to as a source-line side non-selected memory cell MC. In addition, non-selected word-lines WL_L+1 to WL_M−1 connected to the bit-line side non-selected memory cells MC are referred to as bit-line side non-selected word-lines WL_L+1 to WL_M−1. In addition, non-selected word-lines WL_K+1 to WL_L connected to the central region non-selected memory cells MC are referred to as central region non-selected word-lines WL_K+1 to WL_L. In addition, non-selected word-lines WL_0 to WL_K connected to the source-line side non-selected memory cells MC are referred to as source-line side non-selected word-lines WL_0 to WL_K. Note that although the first boundary B₁ is set between the non-selected word-line WL_L and the non-selected word-line WL_L+1, this is merely an example. Likewise, although the second boundary B₂ is set between the non-selected word-line WL_K and the non-selected word-line WL_K+1, this is merely an example.

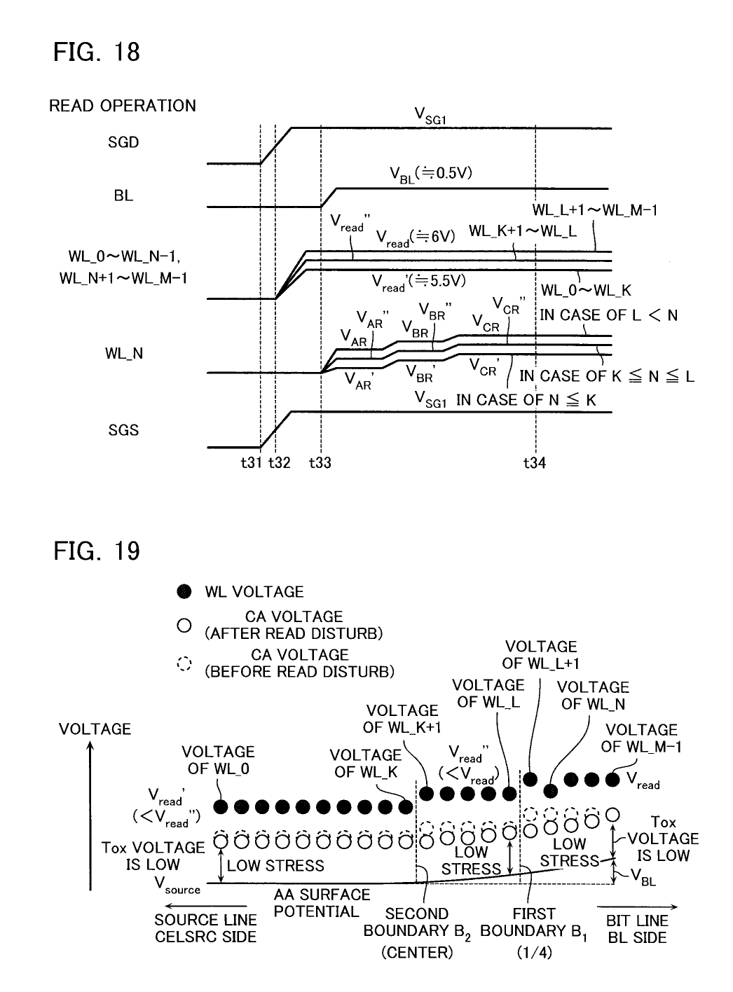

FIG. 18 is a timing diagram for illustrating the read operation according to this embodiment.

As shown in FIG. 18, in the read operation according to this embodiment, at a timing t32, the bit-line side non-selected word-lines WL_L+1 to WL_M−1 are applied with the first read-pass voltage V_{read} (for example, about 6 V). In addition, the central region non-selected word-lines WL_K+1 to WL_L are applied with a third read-pass voltage V_{read}″ less than the first read-pass voltage V_{read}. In addition, the source-line side non-selected word-lines WL_0 to WL_K are applied with the second read-pass voltage V_{read}′ (for example, about 5.5 V) less than the third read-pass voltage V_{read}″. This switches the non-selected memory cells MC_0 to MC_N−1 and MC_N+1 to MC_M−1 to the ON state, thereby changing the voltage of the semiconductor layer AA of these cells to the source voltage V_{source}. Note that the source voltage V_{source} is set to, by way of example, the ground voltage.

In addition, if the selected memory cell MC_N is set on the bit-line BL side of the first boundary B₁ (L<N), the read voltage applied to the selected memory cell MC_N is sequentially increased to V_{AR}, V_{BR}, and V_{CR} from timing t33. In addition, if the selected memory cell MC_N is positioned between the first boundary B₁ and the second boundary B₂ (K≦N≦L), the read voltage applied to the selected memory cell MC_N is sequentially increased to V_{AR}″ less than V_{AR}, V_{BR}″ less than V_{BR}, and V_{CR}″ less than V_{CR} from timing t33. In addition, if the selected memory cell MC_N is set on the source-line CELSRC side of the second boundary B₂ (N≦K), the read voltage applied to the selected memory cell MC_N is sequentially increased to V_{AR}′ less than V_{AR}″, V_{BR}′ less than V_{BR}″, and V_{CR}′ less than V_{CR}″ from timing t33.

In addition, as shown in FIG. 18, the read operation according to this embodiment is similar in other respects to the read operation according to the first embodiment, and at timings t31 to t34, the operation at timings t11 to t14 described with reference to FIG. 10 is performed.

FIG. 19 is a diagram schematically showing the voltage relationship between the semiconductor layer AA, the charge accumulation layer CA, and the word-lines WL in the read operation according to this embodiment. In addition, in FIG. 19, the open circles with dotted lines represent the voltage of the charge accumulation layer CA before the read disturb occurs, the open circles with solid lines represent the voltage of the charge accumulation layer CA after the read disturb occurs, and the closed circles represent the voltage of the word-lines WL.

As shown by the dotted line in FIG. 19, the read operation according to this embodiment sets the first boundary B₁ between the memory cell MC_L (K<L<M−1) and the memory cell MC_L+1. In addition, the read operation according to this embodiment sets the second boundary B₂ between the memory cell MC_K and the memory cell MC_K+1. In addition, as shown by the closed circles in FIG. 19, the bit-line side non-selected word-lines WL_L+1 to WL_M−1 are applied with the first read-pass voltage V_{read}. In addition, the central region non-selected word-lines WL_K+1 to WL_L are applied with the third read-pass voltage V_{read}″ less than the first read-pass voltage V_{read}. In addition, the source-line side non-selected word-lines WL_0 to WL_K are applied with the second read-pass voltage V_{read}′ less than the third read-pass voltage V_{read}″.

In other words, in this embodiment, two boundaries B₁ and B₂ are set in the NAND cell unit, and the non-selected word-line voltage is decreased in a stepped manner utilizing the two boundaries B₁ and B₂ as borders from the bit-line BL side to the source-line SELSRC side. Thus, the Tox voltage of the non-selected memory cell MC can be adjusted more flexibly than the first embodiment, thus the generation of the read disturb can be more suitably reduced.

Note that, in this embodiment, the first boundary B₁ is set at one-fourth from the bit-line BL side of the NAND cell unit and the second boundary B₂ is set in the central portion of the NAND cell unit. However, the predetermined boundaries B₁ and B₂ may be set to any positions.

In addition, in the first and second embodiments, one predetermined boundary B is set in the NAND cell unit and in the third embodiment, two predetermined boundaries are set in the NAND cell unit. However, three or more predetermined boundaries may be set in the NAND cell unit. In this case, for example, the non-selected word-line voltage may be decreased in a stepped manner utilizing the boundaries as borders from the bit-line BL side to the source-line SELSRC. In other words, at all boundaries, the voltages of the non-selected word-lines WL positioned on the source-line CELSRC side of the boundary may be set less than the voltages of the non-selected word-lines WL positioned on the bit-line BL side of the boundary. In addition, in a plurality of regions separated by the boundaries in the NAND cell unit, the voltages of the non-selected word-lines WL may be set to the same or similar values.

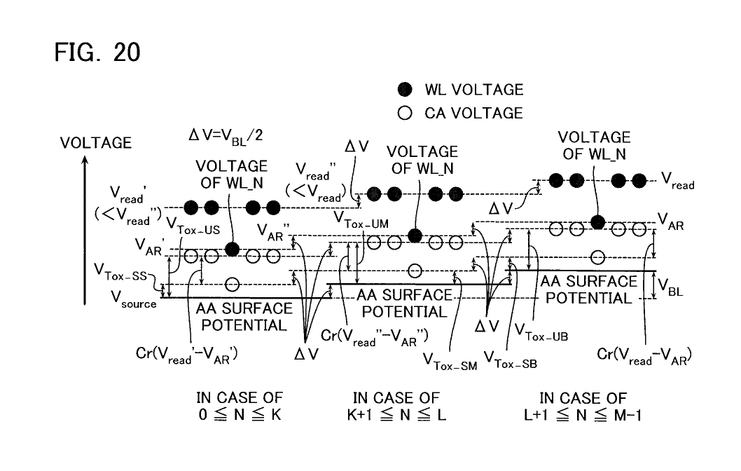

Next, with reference to FIG. 20, the Tox voltage of the selected memory cell MC in the read operation according to the third embodiment will be described. FIG. 20 is a diagram schematically showing the voltage relationship between the semiconductor layer AA, the charge accumulation layer CA, and the word-lines WL in the read operation according to this embodiment. In FIG. 20, the open circles represent the voltage of the charge accumulation layer CA and the closed circles represent the voltage of the word-lines WL. Note that FIG. 20 illustrates an example where the selected memory cell MC_N is in the ON state. Note that in the following discussion, like elements as those in the read operation according to the second embodiment are designated with like reference symbols and their description is omitted here.

As shown in FIG. 20, in this embodiment, between when the selected memory cell MC_N is set on the bit-line BL side of the first boundary B₁ (L+1≦N≦M−1), when the selected memory cell MC_N is positioned between the first boundary B₁ and the second boundary B₂ (K+1≦N≦L), and when the selected memory cell MC_N is set on the source-line CELSRC side of the second boundary B₂ (0≦N≦K), the voltage of the selected word-line WL_N is adjusted such that the selected memory cell MC_N has similar Tox voltages for these cases.

In other words, if the selected memory cell MC_N is set on the bit-line BL side of the first boundary B₁ (L+1≦N≦M−1), the selected word-line WL_N is applied with the first read voltage (for example V_{AR}). In addition, if the selected memory cell MC_N is positioned between the first boundary B₁ and the second boundary B₂ (K+1≦N≦L), the selected word-line WL_N is applied with a third read voltage (for example V_{AR}′) less than the first read voltage. In addition, if the selected memory cell MC_N is set on the source-line CELSRC side of the second boundary B₂ (0≦N≦K), the selected word-line WL_N is applied with a second read voltage (for example V_{AR}′) less than the third read voltage.

In addition, the first to third read voltages (for example V_{AR}, V_{AR}″, and V_{AR}′) are set to equalize Cr(V_{read}−V_{AR}), Cr(V_{read}″−V_{AR}″), and Cr(V_{read}′−V_{AR}′).

Thus, between when the selected memory cell MC_N is positioned on the bit-line BL side of the first boundary B₁ (L+1≦N≦M−1), when the selected memory cell MC_N is positioned between the first boundary B₁ and the second boundary B₂ (K+1≦N≦L), and when the selected memory cell MC_N is positioned on the source-line CELSRC side of the second boundary B₂ (0≦N≦K), the Tox voltages of the selected memory cell MC_N may be adjusted to similar values, thus suitably reducing the generation of the misreading.

In addition, the above predetermined boundaries B₁ and B₂ are set to constant positions regardless of the position of the selected memory cell MC_N. In addition, if the selected memory cell MC_N is positioned on the bit-line BL side of the first boundary B₁, the selected word-line WL_N is always applied with the first read voltages V_{AR}, V_{BR}, and V_{CR}. Likewise, if the selected memory cell MC_N is positioned between the first boundary B₁ and the second boundary B₂, the selected word-line WL_N is always applied with the third read voltages V_{AR}″, V_{BR}″, and V_{CR}″. Likewise, if the selected memory cell MC_N is positioned on the source-line CELSRC side of the second boundary B₂, the selected word-line WL_N is always applied with the second read voltages V_{AR}′, V_{BR}′, and V_{CR}′. Therefore, predetermined voltages need only be transferred to predetermined word-lines WL, which can be achieved without employing a complicated configuration in the row control circuit 3 and the voltage generation circuit 10 or the like.

Note that it is considered that the difference ΔV between the first read voltages (V_{AR}, V_{BR}, and V_{CR}), the third read voltages (V_{AR}″ V_{BR}″, and V_{CR}″), and the second read voltages (V_{AR}′, V_{BR}′, and V_{CR}′) is set similar to ΔV between the first read-pass voltage V_{read}, the third read-pass voltage V_{read}″, and the second read-pass voltage V_{read}′. Thus, between when the selected memory cell MC_N is positioned between the first boundary B₁ and the second boundary B₂, when the selected memory cell MC_N is positioned on the source-line CELSRC side of the second boundary B₂, and when the selected memory cell MC_N is positioned on the bit-line BL side of the first boundary B₁, the Tox voltage of the selected memory cell MC_N may be made uniform, thus suitably suppressing the generation of the misreading. For example, as shown in FIG. 20, it is considered that if the second read-pass voltage V_{read}′ is set to about V_{read}″−V_{BL}/2 the second read voltages V_{AR}′, V_{BR}′, and V_{CR}′ are set to about V_{AR}″−V_{BL}/2, V_{BR}″−V_{BL}/2, and V_{CR}″/2, respectively. In addition, as shown in FIG. 20, it is considered that if the third read-pass voltage V_{read}″ is set to about V_{read}−V_{BL}/2, the third read voltages V_{AR}″, V_{BR}″, and V_{CR}″ are set to about V_{AR}−V_{BL}/2, V_{BR}−V_{BL}/2, and V_{CR}−V_{BL}/2, respectively.

In addition, if, for example, three or more predetermined boundaries are set in the NAND cell unit, the selected word-line voltage may be decreased in a stepped manner utilizing the boundaries as borders from the bit-line BL side to the source-line SELSRC side. In other words, at all boundaries, if a word-line WL positioned on the source-line CELSRC side of the boundary is selected, the selected word-line WL_N may be applied with a voltage lower than a voltage applied when a word-line WL positioned on the bit-line BL side of the boundary is selected. In addition, if word-lines WL in the same region separated by a boundary in the NAND cell unit are selected, the selected word-lines WL_N may be applied with the same or similar voltages.

### Fourth Embodiment

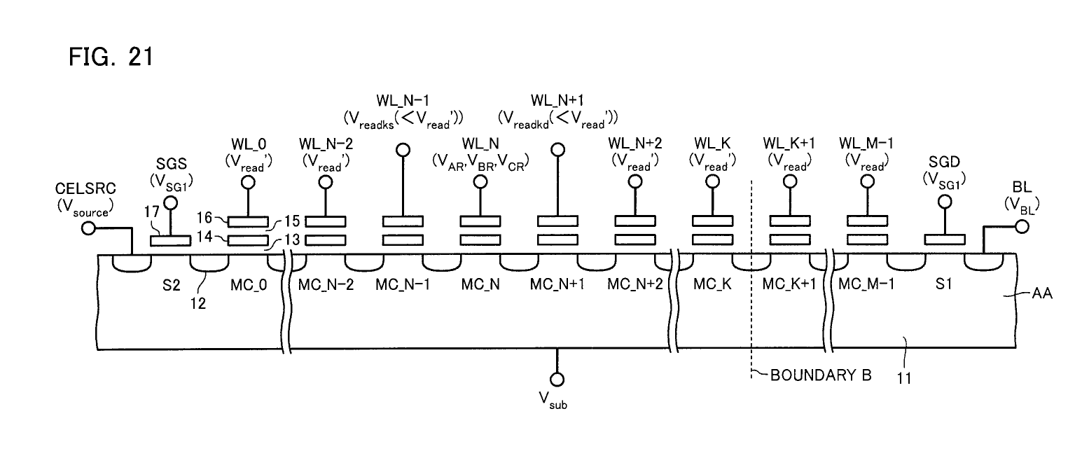

Next, with reference to FIG. 21 to FIG. 24, a non-volatile semiconductor memory device according to a fourth embodiment will be described. Note that in the following discussion, like elements as those in the read operation according to the first embodiment are designated with like reference symbols and their description is omitted here.

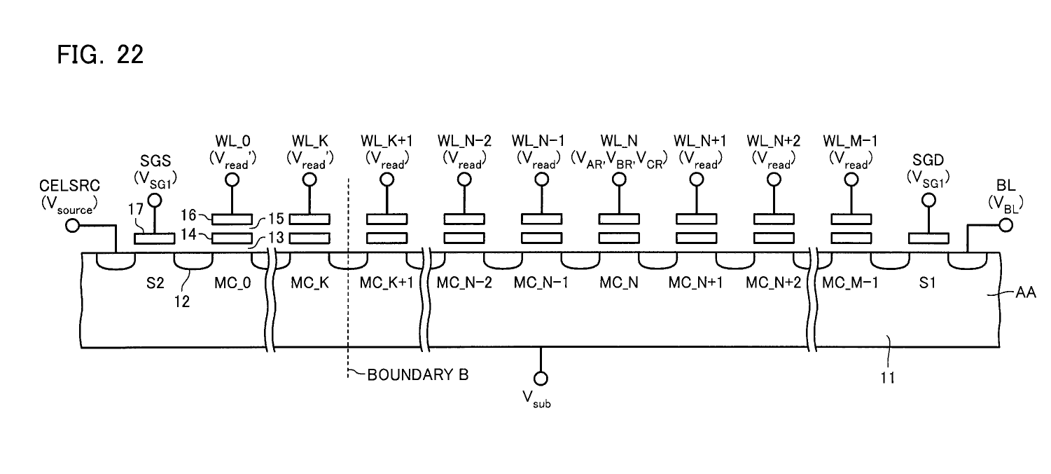

FIG. 21 and FIG. 22 are schematic cross-sectional views of the memory cells MC_0 to MC_M−1 and the select gate transistors S1 and S2 for illustrating the read operation according to this embodiment. As described with reference to FIG. 14, the read operation according to the second embodiment adjusts a voltage applied to the selected word-line WL_N to adjust the Tox voltage in the selected memory cell MC_N, thereby reducing the misreading. In contrast, as shown in FIG. 21 and FIG. 22, the read operation according to this embodiment adjusts the voltage applied not to the selected word-line WL_N but to the non-selected word-lines WL_N−1 and WL_N+1, which are adjacent to the selected word-line WL_N, to adjust the Tox voltage in the selected memory cell MC_N. In other respects, the read operation according to this embodiment is similar to that according to the second embodiment.

Note that in the following discussion, the non-selected memory cells MC_N−1 and MC_N+1 adjacent to the selected memory cell MC_N are referred to adjacent memory cells MC_N−1 and MC_N+1, and the non-selected word-lines WL_N−1 and WL_N+1 connected to the adjacent memory cells MC are referred to as adjacent word-lines WL_N−1 and WL_N+1.

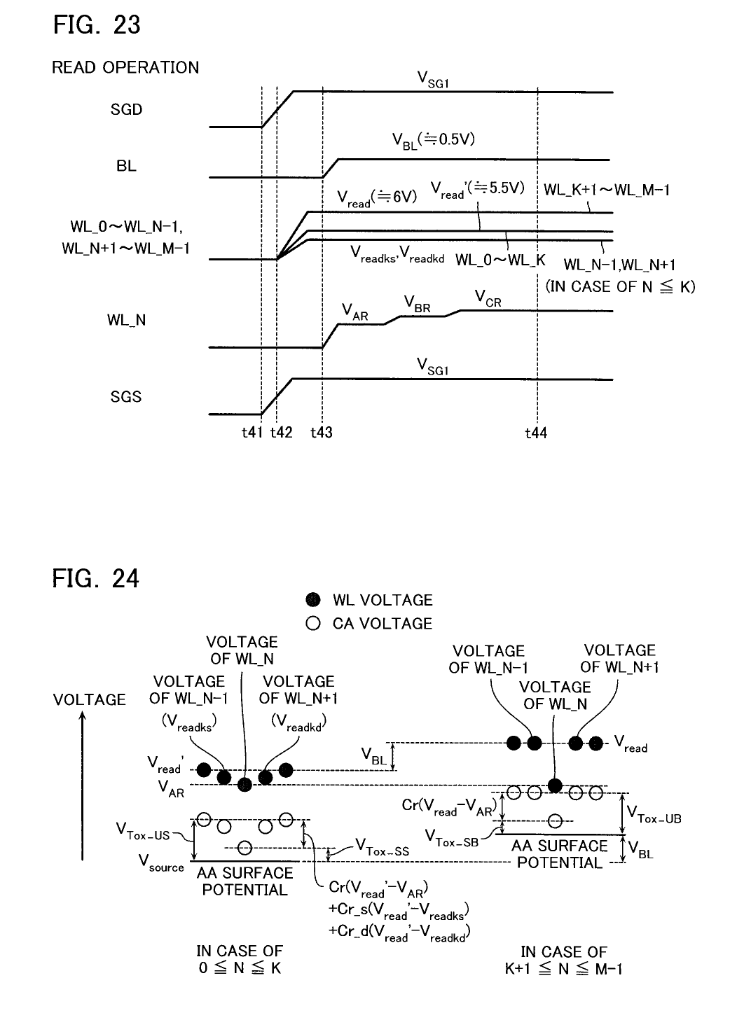

FIG. 23 is a timing diagram for illustrating the read operation according to this embodiment. As shown in FIG. 23, in the read operation according to this embodiment, if the selected memory cell MC_N is set on the bit-line BL side of the predetermined boundary B (K<N), the adjacent word-lines WL_N−1 and WL_N+1 are applied, from timing t42, with the first read-pass voltage V_{read} like other non-selected word-lines WL. Meanwhile, if the selected memory cell MC_N is set on the source-line CELSRC side of the predetermined boundary B (N≦K), the adjacent word-lines WL_N−1 and WL_N+1 are applied, from timing t42, with V_{readks} and V_{readkd} less than the second read-pass voltage V_{read}′. In addition, as shown in FIG. 23, the read operation according to this embodiment is similar in other respects to the read operation according to the first embodiment, and at timings t41 to t44, the operation at timings t11 to t14 described with reference to FIG. 10 is performed.

Next, with reference to FIG. 24, the Tox voltages of the selected memory cell MC_N according to this embodiment will be described. FIG. 24 is a diagram schematically showing the voltage relationship between the semiconductor layer AA, the charge accumulation layer CA, and the word-lines WL in the read operation according to this embodiment. In addition, in FIG. 24, the open circles represent the voltage of the charge accumulation layer CA and the closed circles represent the voltage of the word-lines WL. Note that FIG. 24 illustrates an example where the selected memory cell MC_N is in the ON state.

As described above, in this embodiment, the Tox voltage V_{Tox}_{_{—}}_{US} of the non-selected memory cells MC near the source-line CELSRC is equal to the Tox voltage V_{Tox}_{_{—}}_{UB} of the non-selected memory cells MC near the bit-line BL.

The right diagram of FIG. 24 shows the state if the selected memory cell MC_N is set on the bit-line BL side of the predetermined boundary B (K+1≦N≦M−1). As shown in the right diagram of FIG. 24, the voltage of the charge accumulation layer CA of the selected memory cell MC is lower than the voltage of the charge accumulation layer CA of the non-selected memory cell MCs by about Cr(V_{read}−V_{AR}), where Cr is the coupling ratio.

The left diagram of FIG. 24 shows the state if the selected memory cell MC_N is set on the source-line CELSRC side of the predetermined boundary B (0≦N≦K). As shown in the left diagram of FIG. 24, the voltage of the charge accumulation layer CA of the selected memory cell MC is lower than the voltage of the charge accumulation layer CA of the non-selected memory cells MC by about Cr (V_{read}′−V_{AR})+Cr_s (V_{read}′−V_{readks})+Cr_d (V_{read}′−V_{readkd}), where Cr_s is the coupling ratio between the adjacent word-line WL_N−1 and the charge accumulation layer CA of the selected memory cell MC_N, and Cr_d is the coupling ratio between the adjacent word-line WL_N+1 and the charge accumulation layer CA of the selected memory cell MC_N.

Therefore, by setting V_{readks} and V_{readkd} such that Cr_s(V_{read}′−V_{readks})+Cr_d(V_{read}′−V_{readkd}) is about Cr(V_{read}−V_{read}′), the Tox voltages V_{Tox}_{_{—}}_{SB} and V_{Tox}_{_{—}}_{SS} of the selected memory cell MC_N are adjusted to similar values between when the selected memory cell MC_N is positioned on the bit-line BL side of the predetermined boundary B and when the selected memory cell MC_N is positioned on the source-line CELSRC side of the predetermined boundary B. This may suitably reduce the generation of the misreading.

In addition, this embodiment uses the same read voltage regardless of which memory cell MC is the selected memory cell MC_N. Therefore, predetermined voltages need only be transferred to predetermined word-lines WL and the number of used voltages is less than that in the first and second embodiments, which may be achieved without employing a complicated configuration in the row control circuit 3 and the voltage generation circuit 10 or the like.

Note that in the examples shown in FIG. 23 and FIG. 24, both of V_{readks} and V_{readkd} are set to the same voltage V_{read}−V_{AR}. However, these voltages may be set to different values. In addition, in this embodiment, both of the adjacent word-lines WL_N−1 and WL_N+1 are applied with lower voltages than the other non-selected word-lines. However, only one of the adjacent word-lines WL_N−1 and WL_N+1 may be applied with a lower voltage than the other non-selected word-lines. In addition, the voltage applied to the selected word-line WL_N and the voltages applied to the adjacent word-lines WL_N−1 and WL_N+1 may be adjusted together.

In addition, in this embodiment, two or more predetermined boundaries may also be set and the voltages of the adjacent word-lines WL_N−1 and WL_N+1 may also be adjusted in a stepped manner utilizing the boundaries as a border from the bit-line BL side to the source-line SELSRC side, thus the Tox voltage of the selected word-line WL_N may be adjusted in a stepped manner.

### Fifth Embodiment

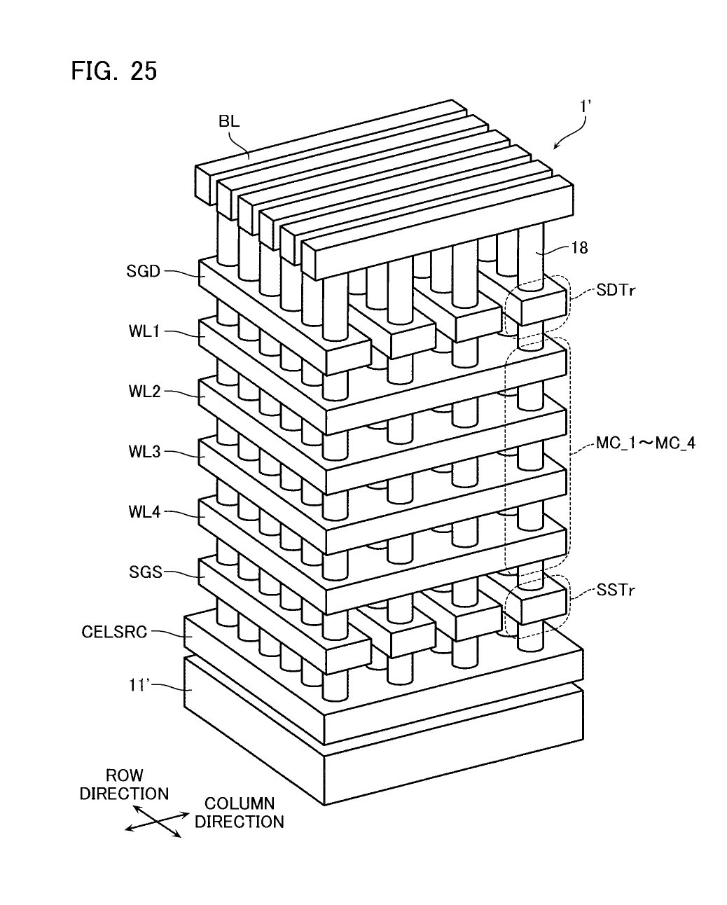

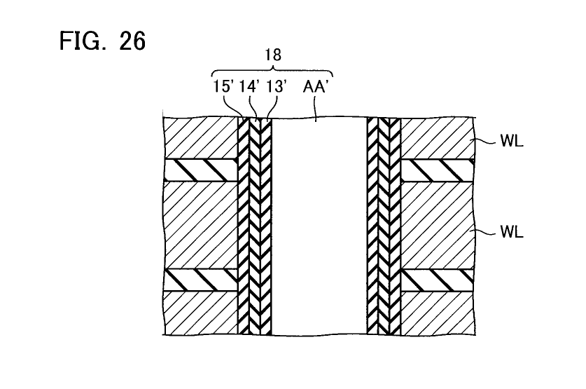

Next, with reference to FIG. 25 and FIG. 26, a fifth embodiment will be described. FIG. 25 is a schematic perspective view showing the configuration of a memory cell array 1′ according to the fifth embodiment. FIG. 26 is an enlarged cross-sectional view showing the configuration of a portion of the memory cell array 1′ shown in FIG. 25.

Specifically, in the first to fourth embodiments, as shown in FIG. 3 for example, the memory cell array 1 comprising the memory cells MC disposed two-dimensionally, each memory cell MC comprising, on the substrate, the n-type diffusion layer 12, the tunnel insulating film 13, the charge accumulation layer 14, the inter-gate dielectric film 15, and the control gate 16 is used. However, the read operations according to the above first to fourth embodiments are also applicable to a non-volatile semiconductor memory device that comprises the memory cell array 1′ comprising memory cells MC arranged in a three dimensional manner, as shown in FIG. 25.

As shown in FIG. 25, the memory cell array 1′ comprises the source-line CELSRC extending like a plate on a semiconductor substrate 11′ and a plurality of columnar shape semiconductor layers 18 on the source-line CELSRC, the columnar shape semiconductor layers 18 extending upward in a vertical direction. The semiconductor layers 18 are arranged in a matrix in the column and row directions. In addition, above the memory cell array 1′, a plurality of bit-lines BL extending in the column direction are arranged in the row direction. The semiconductor layers 18 arranged in the column direction are connected to a common bit-line BL at the upper ends thereof.

Each semiconductor layer 18 comprises, as shown in FIG. 26, which is a partially enlarged cross-section of the semiconductor layer 18, a columnar shape semiconductor body AA′, a tunnel insulating film 13′ covering the side surface of the semiconductor body AA′, a charge accumulation layer 14′, and an inter-gate dielectric film 15′. Specifically, the semiconductor body AA′ is surrounded by the tunnel insulating film 13′, the tunnel insulating film 13′ is surrounded by the charge accumulation layer 14′, and the charge accumulation layer 14′ is surrounded by the inter-gate dielectric film 15′. In addition, the inter-gate dielectric film 15′ is further surrounded by word-lines WL. The semiconductor body AA′ comprises, for example, polysilicon.

As shown in FIG. 25, conductive layers are laminated via insulating layers around the columnar shape semiconductor layers 18. The conductive layers form, from the semiconductor substrate 11′ side to upward in a vertical direction, the select gate line SGS on the source-line CELSRC side, the word-lines WL4, WL3, WL2, and WL1, and the select gate line SGD on the bit-line BL side. These conductive layers are connected to the side surfaces of the semiconductor layers 18. Thus, the memory cells MC_1 to MC_4 are formed, comprising the word-lines WL1 to WL4 as the control gates and the columnar shape semiconductor body AA′ as a channel body. In addition, the source-side select gate line SGS and the drain-side select gate line SGD are used as the gates and the columnar shape semiconductor body AA′ is used as the channel body to provide a source-side select gate transistor SSTr and a drain-side select gate transistor SDTr, respectively.

As illustrated in FIG. 25 and FIG. 26, in the memory cell array 1′ comprising the memory cells MC arranged in a three dimensional manner, the semiconductor body AA′ may comprise polysilicon and thus easily have a larger channel resistance than that in the flat memory cell array 1 illustrated in FIG. 3. In addition, in the memory cell array 1′, each memory cell MC is becoming finer and increasing in the integration density. Therefore, as described above, the read bit-line voltage V_{BL} is increasing. Thus, the operations according to the first to fourth embodiments may effectively reduce the generation of the read disturb.

Note that although FIG. 25 shows the so-called I-type structure in which each semiconductor layer 18 is formed in a columnar shape, the so-called U-type structure may also be used in which each semiconductor layer 18 in a columnar shape is connected at its lower end, thus forming a U-type semiconductor layer.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a NAND cell unit comprising a plurality of memory cells connected in series and storing the same bit number of data;
a bit-line connected to an end of the NAND cell unit;
a source-line connected to the other end of the NAND cell unit;
a plurality of word-lines connected to respective control gates of the plurality of memory cells; and
a control circuit controlling voltage of the bit-line, the source-line and the plurality of the word-lines,
the control circuit
applying a read voltage to a selected word-line connected to a selected memory cell, the read voltage turning on or turning off the selected memory cell according to a cell data stored to the selected memory cell,
applying, to a non-selected word-line connected to a non-selected memory cell positioned on the bit-line side of a predetermined boundary in the NAND cell unit and positioned farther from the selected memory cell than a predetermined value, a first read-pass voltage turning on the non-selected memory cell regardless of cell data, an amount of the first read-pass voltage being regardless of a position of the selected memory cell, and
applying, to a non-selected word-line connected to a non-selected memory cell positioned on the source-line side of the predetermined boundary and positioned farther from the selected memory cell than a predetermined value, a second read-pass voltage less than the first read-pass voltage, an amount of the second read-pass voltage being regardless of the position of the selected memory cell.

2. The non-volatile semiconductor memory device according to claim 1, wherein
the position of the predetermined boundary is constant regardless of the position of the selected memory cell.

3. The non-volatile semiconductor memory device according to claim 1, wherein
a position of the predetermined boundary in the NAND cell unit is set closer to the bit-line than a center of the NAND cell unit.

4. The non-volatile semiconductor memory device according to claim 2, wherein
a position of the predetermined boundary in the NAND cell unit is set closer to the bit-line than a center of the NAND cell unit.

5. The non-volatile semiconductor memory device according to claim 1, wherein
the control circuit
applies, if the selected memory cell is positioned on the bit-line side of the boundary, a first read voltage to the selected word-line, and
applies, if the selected memory cell is positioned on the source-line side of the boundary, a second read voltage less than the first read voltage to the selected word-line.

6. The non-volatile semiconductor memory device according to claim 1, wherein
a plurality of said predetermined boundaries is set in the NAND cell unit, and
the voltage applied to the non-selected word-line connected to the non-selected memory cell positioned farther from the selected memory cell than the predetermined value does not depend on the position of the selected memory cell in value and decreases in a stepped manner utilizing the predetermined boundaries as a border from the bit-line side to the source-line side.

7. The non-volatile semiconductor memory device according to claim 1, wherein
the control circuit
applies, if the selected memory cell is positioned on the bit-line side of the predetermined boundary, the first read-pass voltage to an adjacent word-line connected to an adjacent memory cell adjacent to the selected memory cell,
applies, if the selected memory cell is positioned on the source-line side of the predetermined boundary, a read-pass voltage less than the second read-pass voltage to the adjacent word-line.

8. The non-volatile semiconductor memory device according to claim 5, wherein
the control circuit
applies, if the selected memory cell is positioned on the bit-line side of the predetermined boundary, the first read-pass voltage to an adjacent word-line connected to an adjacent memory cell adjacent to the selected memory cell, and
applies, if the selected memory cell is positioned on the source-line side of the predetermined boundary, a read-pass voltage less than the second read-pass voltage to the adjacent word-line.

9. A method of controlling a non-volatile semiconductor memory device, the non-volatile semiconductor memory device comprising:
a NAND cell unit comprising a plurality of memory cells connected in series and storing the same bit number of data;
a bit-line connected to an end of the NAND cell unit;
a source-line connected to the other end of the NAND cell unit;
a plurality of word-lines connected to respective control gates of the plurality of memory cells; and
a control circuit controlling voltage of the bit-line, the source-line and the plurality of the word-lines,
the method comprising:
applying a read voltage to a selected word-line connected to a selected memory cell, the read voltage turning on or turning off the selected memory cell according to a cell data stored to the selected memory cell;
applying, to a non-selected word-line connected to a non-selected memory cell positioned on the bit-line side of a predetermined boundary in the NAND cell unit and positioned farther from the selected memory cell than a predetermined value, a first read-pass voltage turning on the non-selected memory cell regardless of cell data, an amount of the first read-pass voltage being regardless of a position of the selected memory cell; and
applying, to a non-selected word-line connected to a non-selected memory cell positioned on the source-line side of the predetermined boundary and positioned farther from the selected memory cell than a predetermined value, a second read-pass voltage less than the first read-pass voltage, an amount of the second read-pass voltage being regardless of the position of the selected memory cell.

10. The method of controlling a non-volatile semiconductor memory device according to claim 9, wherein
the position of the predetermined boundary is constant regardless of the position of the selected memory cell.

11. The method of controlling a non-volatile semiconductor memory device according to claim 9, wherein
a position of the predetermined boundary in the NAND cell unit is set closer to the bit-line than a center of the NAND cell unit.

12. method of controlling a non-volatile semiconductor memory device according to claim 10, wherein
a position of the predetermined boundary in the NAND cell unit is set closer to the bit-line than a center of the NAND cell unit.

13. The method of controlling a non-volatile semiconductor memory device according to claim 9, wherein
if the selected memory cell is positioned on the bit-line side of the boundary, a first read voltage is applied to the selected word-line,
if the selected memory cell is positioned on the source-line side of the boundary, a second read voltage less than the first read voltage is applied to the selected word-line.

14. The method of controlling a non-volatile semiconductor memory device according to claim 9, wherein
a plurality of said predetermined boundaries is set in the NAND cell unit, and
the voltage applied to the non-selected word-line connected to the non-selected memory cell positioned farther from the selected memory cell than the predetermined value does not depend on the position of the selected memory cell in value and decreases in a stepped manner utilizing the predetermined boundaries as a border from the bit-line side to the source-line side.

15. The method of controlling a non-volatile semiconductor memory device according to claim 9, wherein
if the selected memory cell is positioned on the bit-line side of the predetermined boundary, the first read-pass voltage is applied to an adjacent word-line connected to an adjacent memory cell adjacent to the selected memory cell, and
if the selected memory cell is positioned on the source-line side of the predetermined boundary, a read-pass voltage less than the second read-pass voltage is applied to the adjacent word-line.

16. The method of controlling a non-volatile semiconductor memory device according to claim 13, wherein
if the selected memory cell is positioned on the bit-line side of the predetermined boundary, the first read-pass voltage is applied to an adjacent word-line connected to an adjacent memory cell adjacent to the selected memory cell, and
if the selected memory cell is positioned on the source-line side of the predetermined boundary, a read-pass voltage less than the second read-pass voltage is applied to the adjacent word-line.
